(19) United States
(12) Patent Application Publication
(10) Pub. No.: US 2007/0186131 A1
(43) Pub. Date: Aug. 9, 2007

(54) Low cost imbedded load board diagnostic test fixture

(75) Inventor: Corey Jason Goodrich, Allen, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/348,041

(22) Filed: Feb. 6, 2006

(51) Int. Cl. G01R 31/28

(52) U.S. Cl. 714/724

(57) ABSTRACT

In a method and system for testing an intermediary device, a tester provides a test signal to a device under test (DUT) via a first circuit path on the intermediary device. A first response is received from the DUT to verify that the DUT and the first circuit path are substantially free from defects. The DUT is configured to include a second circuit path to be tested. The test signal is provided by the DUT to the second circuit path. A second response is received from the DUT to verify that the second circuit path is substantially free from defects. In a similar manner, the DUT is configured to include additional components of the intermediary device to be tested.

### BACKGROUND

The present disclosure relates generally to test systems, and more particularly to a system and method for testing intermediary devices and circuit paths, which provide electrical coupling between a tester and a device under test (DUT).

Manufacturers of electrical/electronic devices such as integrated circuits (ICs), including system-on-a-chip (SoC), radio frequency (RF) circuit devices, printed circuit boards, and other electronic circuits, typically use automatic test equipment (ATE), testers or similar other test systems to test the devices during the production process. The test systems are generally configured to apply a test signal to the DUT and measure its response to determine a pass or fail status. The DUT is typically mounted on a load board (which may also be referred to as a test board, an interface board, an auxiliary board, a DUT board and similar other). The load board is removably secured to a test head of the tester. Test signals generated by the tester are communicated to the DUT via the test head and the load board.

Typically, the load board is a custom designed printed circuit board (PCB) that serves as an ‘interface’ between the tester and the DUT. That is, an intermediary device in the form of the load board may not be available as an off-the-shelf load board and is generally adapted for use with a particular type of tester and the DUT. The intermediary device may include electronic components such as IC's, resistors, capacitors, inductors, relays, and various types of connectors, pins, conductors, cables, lines, links, traces, buses, and the like. Many load boards may use the electronic components to provide additional test capabilities that the tester may not be able to provide in a cost effective manner.

It is desirable that the load board may not introduce distortion, noise, delays, electrical faults and/or errors in the testing process of the DUT. However, in a real-world, manufacturing environment, failures may occur in the DUT and/or in the load board. Failures in the load board may be improperly binned (or classified) as DUT failures, even though the DUT may be operating properly. Even worse, failure of load board may occasionally result in acceptance of faulty DUT's, costing the manufacturer millions of dollars. As a result, some of the limitations of the test system may result in producing a higher than desirable failure rate and an increase in waste, thereby slowing down the production rate and increasing the cost of testing and production.

Therefore, a need exists to provide an efficient method and system for testing the load board coupled to the DUT. Specifically, a need exists to test the entire electrical path between the tester and the DUT, including any intermediary devices and components and/or connectors thereof. Accordingly, it would be desirable to provide an improved test system for testing intermediary devices, absent the disadvantages found in the prior methods discussed above.

### SUMMARY

The foregoing need is addressed by the teachings of the present disclosure, which relates to a system and method for testing an intermediary device. According to one embodiment, in a method and system for testing an intermediary device, a tester provides a test signal to a device under test (DUT) via a first circuit path on the intermediary device. A first response is received from the DUT to verify that the DUT and the first circuit path are substantially free from defects. The DUT is configured to include a second circuit path to be tested. The test signal is provided by the DUT to the second circuit path. A second response is received from the DUT to verify that the second circuit path is substantially free from defects. In a similar manner, the DUT is configured to include additional components of the intermediary device to be tested.

In one aspect of the disclosure, a method for testing a relay included on an intermediary device coupled to a device under test (DUT) includes placing the DUT in a test mode, thereby enabling testing of the DUT in accordance with the IEEE 1149.1 standard. The relay is closed to enable a loop back path. The boundary scan chain for the DUT is configured to originate with the TDI pin input and terminating with the TDO pin output. The relay is coupled to the boundary scan chain via the primary input and the primary output, with the primary input and the primary output being coupled to a boundary scan cell each. A predefined logic signal, e.g., a logic high level signal, is provided to the TDI pin input. A response is received at the TDO pin in response to the predefined logic signal. The relay is verified to be substantially free from defects if the response matches the predefined logic signal.

Several advantages are achieved by the method and system according to the illustrative embodiments presented herein. The embodiments advantageously provide for efficient cost efficient techniques to verify that intermediary devices and components and/or connections thereof are substantially free from defects. This advantageously enables manufacturing facilities to improve quality and properly classify failures of the DUT, thereby reducing wastage due to improper binning, reducing the overall testing costs and enabling increased production.

### BRIEF DESCRIPTION OF THE DRAWINGS

FIG. 1 illustrates a block diagram of a test system for testing an intermediary device, according to an embodiment;

FIG. 2A illustrates a sectional diagram of an intermediary device having multiple boards, according to an embodiment;

FIG. 2B illustrates a sectional diagram of an intermediary device having one board, according to an embodiment;

FIG. 2C illustrates a layout diagram of a load board described with reference to FIG. 2B, according to an embodiment;

FIG. 3 is a flow chart illustrating a method for testing an intermediary device coupled to a device under test, according to an embodiment;

FIG. 4 is a block diagram illustrating a boundary scan chain to verify connectivity of a relay component of an intermediary device, according to an embodiment; and

FIG. 5 is a flow chart illustrating a method for testing a relay included on an intermediary device coupled to a device under test, according to an embodiment.

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices or components described herein may be implemented as hardware (including discrete components, integrated circuits and systems-on-a-chip ‘SoC’), firmware (including application specific integrated circuits and programmable chips) and/or software or a combination thereof, depending on the application requirements.

Many test systems use an intermediary device such as a load board to interface a tester with a device under test (DUT). The intermediary device typically includes electronic components such as IC's, resistors, capacitors, inductors, relays, and various types of connectors, pins, conductors, cables, lines, links, traces, buses, and the like. Failure may occur at any point along a circuit path of the test signal. Presently, it may be difficult to determine whether the failure is due to a defect in the intermediary device and/or due to a defect in the DUT. As a result, a failure may be improperly binned as a failure in the DUT. Additionally, it may take an extended period of time to detect and fix the problem. This problem may be addressed by an improved system and method to test an intermediary device within a test system. In the improved system and method, the DUT is verified to be free from defects. A boundary scan chain of the DUT is then configured to include a predefined electronic component of the intermediary device for testing and verification. The process may be repeated to test other electronic components of the intermediary device.

According to one embodiment, in a method and system for testing an intermediary device, a tester provides a test signal to a device under test (DUT) via a first circuit path on the intermediary device. A first response is received from the DUT to verify that the DUT and the first circuit path are substantially free from defects. The DUT is configured to include a second circuit path to be tested. The test signal is provided by the DUT to the second circuit path. A second response is received from the DUT to verify that the second circuit path is substantially free from defects. In a similar manner, the DUT is configured to include additional components of the intermediary device to be tested.

The following terminology may be useful in understanding the present disclosure. It is to be understood that the terminology described herein is for the purpose of description and should not be regarded as limiting.

Device—Any machine or component that is operable to perform at least one predefined function. Examples of devices may include power supplies, fan assemblies, chargers, controllers, disk drives, scanners, cameras, printers, speakers, keyboards, and communication interfaces.

System—One or more interdependent devices that co-operate to perform one or more predefined functions.

Configuration—Describes a set up of a device and/or a system and refers to a process for setting, defining, or selecting hardware and/or software properties, parameters, or attributes of the device and/or the system.

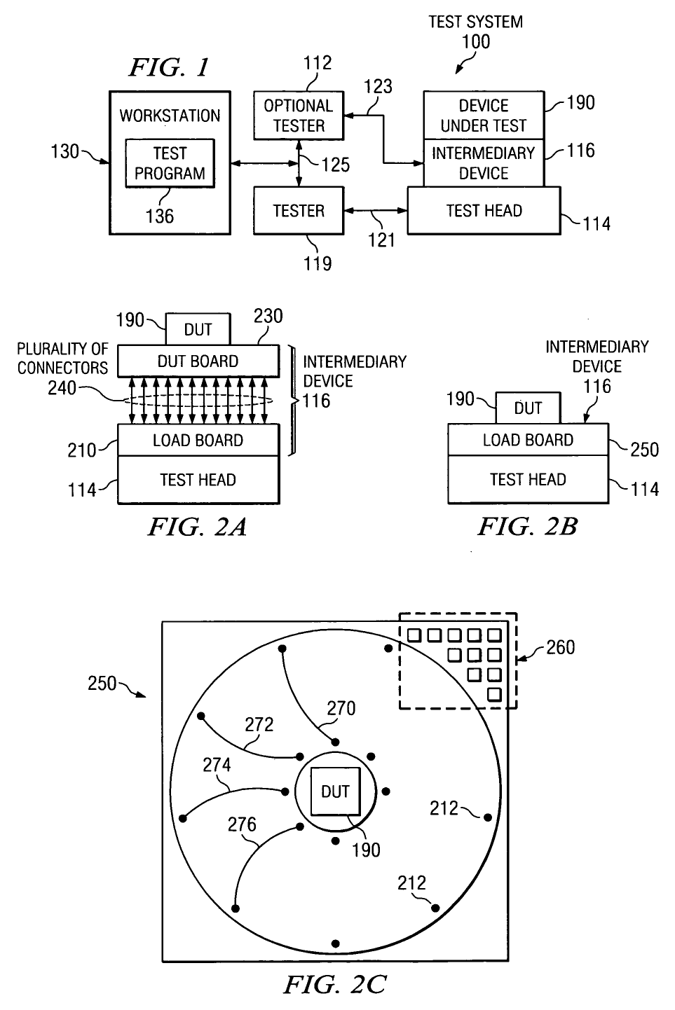

FIG. 1 illustrates a block diagram of a test system 100 for testing an intermediary device 116, according to an embodiment. The test system 100 includes a tester 119 operable to communicate one or more test signals (not shown) to a device under test (DUT) 190 via the intermediary device 116. In a particular embodiment, the intermediary device 116 includes a plurality of circuit paths (not shown) for communicating the test signals. In an embodiment, the intermediary device 116 may be removably secured, e.g., secured in a removable manner, to a test head 114 and the DUT 190 may be removably secured to the intermediary device 116 to enable the electrical coupling. In a particular embodiment, the DUT 190 is at least one of a microprocessor, an application specific integrated circuit (ASIC), a digital signal processor, a radio frequency chip, a memory, a microcontroller and a system-on-a-chip or a combination thereof. Additional detail of the intermediary device 116 is described with reference to FIG.'s 2A, 2B and 2C.

The tester 119 is electrically coupled to the test head 114 via one or more electrical couplers 121 (such as conductors, cables, lines, traces, links, buses and similar others). In a particular embodiment, the test system 100 may include an optional tester 112 for providing one or more particular test signals (not shown) that may not be generated by the tester 119. The optional tester 112 may be electrically coupled to the intermediary device 116 via one or more electrical couplers 123 (such as conductors, cables, lines, traces, links, buses and similar others).

The test signals may include various well known test signal types including alternating current (AC) and/or direct current (DC), analog and/or digital, time and/or frequency, synchronous and/or asynchronous, pulse, clock and similar others. In one embodiment, test signals may include a DC power signal to power the DUT 190, a low speed digital signal having a frequency less than 30 MHz, a radio frequency (RF) signal, and/or a high speed digital (HSD) signal having a frequency greater than or equal to 30 MHz and up to tens of gigahertz.

In the depicted embodiment, the optional tester 112 is electrically coupled to the tester 119 via one or more communications links 125. The links 125 may be implemented by using all or a portion of a bus connection, one or more local area networks (LAN's), metropolitan area networks (MAN's), wide area network (WAN's), a global network such as the Internet, any other appropriate wire line, wireless or other similar communication link.

A workstation 130 is electrically coupled to the communication link 125, and hence to the tester 119 and the optional tester 112. In a particular embodiment, the workstation 130 is a programming device, such as a computer system, operable to generate a test program 136. Multiple programs may be developed to test various aspects of the DUT 190. The workstation 130 may include conversion tools to generate an executable and/or downloadable version from a source code of the test program 136.

In a particular embodiment, the test program 136 includes a stimuli logic to provide the test signals to the DUT 190, a compare logic to receive response signals from the DUT 190, and a decision logic to determine whether the DUT 190 passes or fails the testing. Execution of the test program 136 results in applying test stimuli (also referred to as test vectors) to the DUT 190. In a particular embodiment, the test stimuli may be in the form of providing the test signals to the DUT 190. The test vectors for a particular test may define a sequence of fixed input values and expected output values for a circuit being tested. If the response from the DUT 190 to the test stimuli does not match the expected output values then the DUT 190 may be identified as defective. Test related data such as pass/fail results, time/event data, diagnostic data, and logging data may be provided to the workstation 130 for further analysis.

Various types of the test program 136 may be developed to test device features. In a particular embodiment, the DUT 190 includes support for testing in accordance with the JTAG IEEE 1149-1 standard. This standard advantageously provides a boundary scan architecture to perform system level diagnostics, which may be used to verify connectivity between system components and isolate the system components at the board level for individual tests. For example, test programs may include a boundary scan chain program to test internal circuitry of the DUT 190 and/or one or more components of the intermediary device 116 electrically coupled to the DUT 190. Additional detail of configuring a boundary scan chain to verify connectivity of the intermediary device 116 is described with reference to FIG.'s 3, 4 and 5.

In an exemplary, non-depicted embodiment, the DUT 190 may be positioned by a handler (or prober) to automatically position the DUT 190 for testing. The handler may perform one or more additional functions such as sorting of the DUT 190 according to various types, controlling temperature of a test chamber during heat testing, and/or handling the DUT 190 in any other suitable fashion. In one embodiment, the DUT 190 may be positioned for probing by a prober.

FIG. 2A illustrates a sectional diagram of an intermediary device 116 having multiple boards, according to an embodiment. In the depicted embodiment, the intermediary device 116 includes a bottom load board 210 (also referred to as a test board, an interface board, an auxiliary board and similar others) which may be removably secured (e.g., secured and/or docked in a removable manner) to the test head 114 and a top DUT board 230 (also referred to as a test board, a device board, a device interface board, a mount board, an interface board, an auxiliary board and similar others) which may be removably secured to the load board 210 for testing. The DUT board 230 may include one or more sockets for mounting the DUT 190. In a docked and/or secured position, a plurality of connectors 240, such as pogo style pin connectors, may be used to electrically couple the load board 210 with the DUT mount board 230.

FIG. 2B illustrates a sectional diagram of an intermediary device 116 having one board, according to an embodiment. In the depicted embodiment, the intermediary device 116 includes a load board 250 which may be removably secured (e.g., secured and/or docked in a removable manner) to the test head 114. In this embodiment, the DUT 190 may be suitable to be directly coupled in a removable manner to the intermediary device 116.

FIG. 2C illustrates a layout diagram of a load board 250 described with reference to FIG. 2B, according to an embodiment. In the depicted embodiment, the load board 250 includes conductive pads 212 (or contact points, traces) to route the test signal via a plurality of circuit paths to the DUT 190 and/or to mount a plurality of components (not shown). The plurality of components may include passive and/or active elements such as an IC, a resistor, a capacitor, an inductor and a relay. In the depicted embodiment, the load board 250 includes a plurality of relays 260.

In a particular embodiment, the test system 100 provides N I/O channels to communicate the test signals to the device 190. The particular value of N, which is an integer, may vary by application and tester size. In a particular embodiment, the plurality of relays 260 enable flexible routing of stimulus/response signals to/from the DUT 190.

In the depicted embodiment, the load board 250, and hence the intermediary device 116, includes a first circuit path 270 for communicating one of the test signals. Also shown are second, third and fourth circuit paths 272, 274 and 276 to electrically couple the DUT 190 with at least one of the tester 119 and/or the plurality of components mounted on the load board 250. In an exemplary non-depicted embodiment, the load board 210 may be substantially the same as the load board 250 except for the inclusion of the DUT 190.

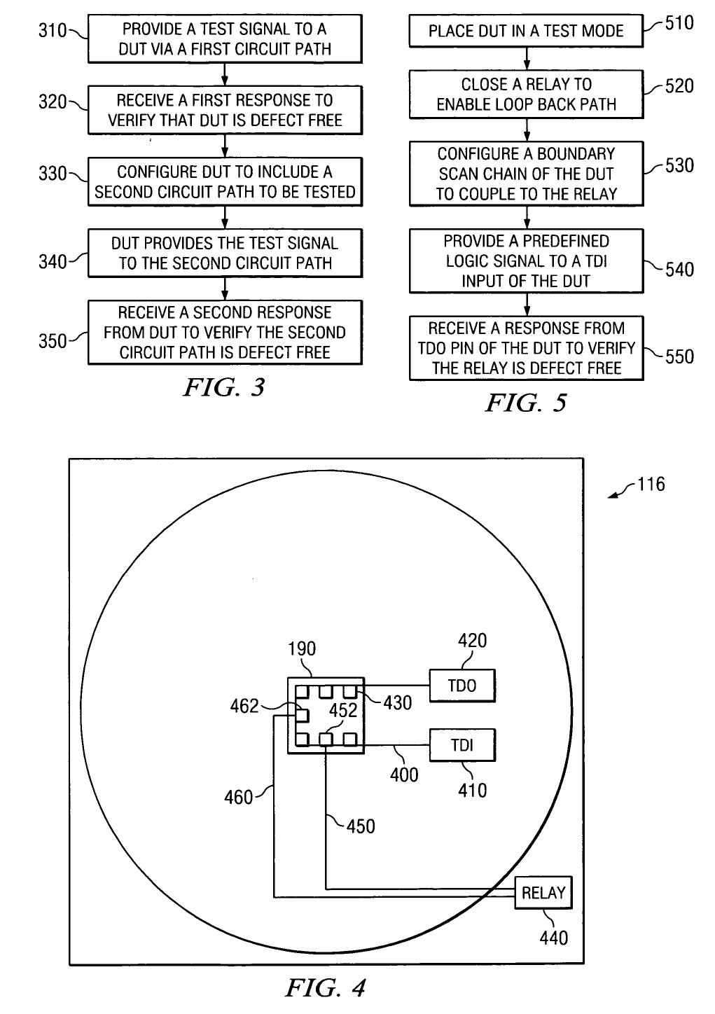

FIG. 3 is a flow chart illustrating a method for testing the intermediary device 116 coupled to the DUT 190, according to an embodiment. At step 310, a test signal is provided to the DUT 190 via the first circuit path 270. At step 320, a first response is received from the DUT 190 to verify that the DUT 190 and the first circuit path 270 are substantially free from defects. Thus, upon verification and validation that the DUT 190 is substantially free from defects, the DUT 190 is now advantageously considered as a correlation unit for the purposes of testing/certifying the intermediary device 210, before the intermediary device 116 is used to conduct tests for additional/new DUT's that may utilize the loop back relays. The substantially defect free DUT 190 is used as the tester to test other circuit paths and/or components of the intermediary device 116. Specifically, when functioning as the tester, a boundary scan chain of the DUT 190 is (re)configurable to include one of the circuit paths or one of the components of the intermediary device 116 to be tested. Additional detail of configuring a boundary scan chain of the DUT 190 is described with reference to FIG. 4. At step 330, the DUT 190 is configured to include the second circuit path 272 to be tested. At step 340, the test signal is provided to the DUT 190. The DUT 190 provides the test signal to the second circuit path 272 since it is included in the boundary scan chain. At step 350, a second response is received from the DUT 190 to verify that the second circuit path 272 is substantially free from defects.

Various steps described above may be added, omitted, combined, altered, or performed in different orders. For example, steps 330, 340, and 350 may be repeated for each one of the other circuit paths or components of the intermediary device 116 that have to be tested. Additional detail of a method for testing a relay component of an intermediary device is described with reference to FIG. 5.

FIG. 4 is a block diagram illustrating a boundary scan chain 400 to verify connectivity of a relay component of the intermediary device 116, according to an embodiment. As IC designs grow more complex, the DUT 190 may include a large number of input/output (I/O) pins (e.g., 1000 to 2000 pins). Many testers have a limited number of I/O channels and thus testing of DUT's having a large pin count may be a challenge. In a particular embodiment, the test system 100 is operable to advantageously deploy a reduced pin-count testing (RPCT) technique.

The RPCT enables application of test patterns using lower-cost testers that may not support a large number of I/O pins. By combining RPCT techniques with the IEEE 1149.1 standard for boundary scan architecture and the IEEE 1149.4 standard for mixed signal and analog assemblies, cost effective testers may be used for testing digital and mixed-signal devices. Thus, the RPCT implementation based on the IEEE 1149.1 and 1149.4 boundary-scan test access port (TAP) interface standard uses the boundary-scan chain 400 that gives full pin access to the tester 119 and virtually eliminates the need to connect each pin of the DUT 190 to the tester 119 (or to the optional tester 112). Specifically, the RPCT technique uses 4 (or optionally 5) pins for testing. The tester 119 primarily drives the clock pins, test control pins, scan-in and scan-out pins, and the test input/output pins of the boundary scan chain 400. The remaining functional I/O pins of the DUT 190 may be accessed through the boundary scan chain 400. After verification and testing of the intermediary device 116 and components and/or conductors thereof, the test system 100 may be used to test another DUT's for a pass or fail status.

In the depicted embodiment, the DUT 190 is placed in a test mode in compliance with the IEEE 1149.1 standard. Boundary scan testing is accomplished via a 4-pin (or optional 5-pin) connection including a test clock (TCK) (not shown), a test mode select (TMS) (not shown), a test data in (TDI) 410, and a test data out (TDO) 420. A boundary scan cell such as a boundary scan cell 430, is defined for each functional I/O (also referred to as primary I/O) pin of the DUT 190. An input to the boundary scan cell 430 may be received via a primary input, a primary output, or from another boundary scan cell, depending on a mode of operation of the DUT 190. A starting point for the boundary scan chain is the TDI pin 410, which receives data/test input, and the ending point for boundary scan chain is the TDO pin 420, which provides the output signal. In a particular embodiment, each one of the boundary scan cells is connected in series in between the TDI pin 410 and the TDO pin 420 to form the boundary scan chain 400. A shift register (not shown) is coupled to each one of the boundary scan cells. Values applied to primary inputs may be captured into the shift register and values that are stored in the shift register may be applied to the primary outputs. A TAP controller (not shown) is a state machine having 16 possible states for controlling operations associated with boundary scan cells.

In the depicted embodiment, the boundary scan chain 400 is configured to include a relay 440. In a particular embodiment, the relay 440 is a selectable one of the plurality of relays 260. Specifically, the relay 440 is coupled to to the boundary scan chain 400 via a primary input 450 associated with a boundary scan cell 452 and a primary output 460 associated with a boundary scan cell 462. Thus, a test signal provided to the TDI pin 410 is also provided to the relay 440. A response received at the TDO pin 420 is used to verify the continuity of the relay 440, since the relay 440 is the new element included in the boundary scan chain 400 and the boundary scan chain 400 has been verified to be substantially free from defects. In a particular embodiment, the workstation 130 may be used to perform the verification. Additional detail of a method for testing the relay 440 is described with reference to FIG. 5.

FIG. 5 is a flow chart illustrating a method for testing a relay included on an intermediary device coupled to a device under test (DUT), according to an embodiment. In a particular mode, the DUT 190 is verified to be substantially free from defects prior to testing the relay 440. At step 510, the DUT 190 is placed in a test mode. In a particular embodiment, the test mode enables testing of the DUT 190 in accordance with the IEEE 1149.1 standard. At step 520, the relay 440 is closed to enable a loop back path. At step 530, the boundary scan chain 400 for the DUT 190 is configured. The boundary scan chain 400 originates with the TDI pin 410 input and terminates with the TDO pin 420 output. The relay 440 is interfaced with the boundary scan chain 400 via the primary output 460 coupled to the boundary scan cell 462 and the primary input 450 coupled to the boundary scan cell 452. At step 540, a predefined logic signal, e.g., a logic high level signal, is provided to the TDI pin 410 input. At step 550, a response is received at the TDO pin 420. The relay 440 is verified to be substantially free from defects if the response is determined to be substantially the same as the predefined logic signal.

Various steps described above may be added, omitted, combined, altered, or performed in different orders. For example, steps 540 and 550 may be repeated with another predefined logic signal, e.g., a logic low level signal. The steps 510, 520, 530, 540 and 550 may be repeated for other components of the intermediary device 116.

Although illustrative embodiments have been shown and described, a wide range of modification, change and substitution is contemplated in the foregoing disclosure and in some instances, some features of the embodiments may be employed without a corresponding use of other features. Those of ordinary skill in the art will appreciate that the hardware and methods illustrated herein may vary depending on the implementation. For example, while certain aspects of the present disclosure have been described in the context of testing relays and conductive traces, those of ordinary skill in the art will appreciate that the processes disclosed are capable of being used for testing any electronic component included in an intermediary device.

The methods and systems described herein provide for an adaptable implementation. Although certain embodiments have been described using specific examples, it will be apparent to those skilled in the art that the invention is not limited to these few examples. The benefits, advantages, solutions to problems, and any element(s) that may cause any benefit, advantage, or solution to occur or become more pronounced are not to be construed as a critical, required, or an essential feature or element of the present disclosure.

The above disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A test system for testing an intermediary device, the test system comprising:
a tester coupled to the intermediary device, the tester being operable to provide a test signal; and
a device under test (DUT) electrically coupled to the intermediary device, wherein the intermediary device includes a plurality of circuit paths for communicating the test signal, wherein the DUT is configurable to include a predefined circuit path of the plurality of circuit paths, wherein the DUT is operable to provide the test signal to the predefined circuit path to verify continuity.

2. The test system of claim 1, wherein the test signal is provided to the DUT via a first circuit path included in the plurality of circuit paths, wherein the DUT provides a first response indicative of a pass or fail status of the DUT.

3. The test system of claim 2, wherein the DUT provides the test signal to the predefined circuit path in response to the DUT having the pass status, wherein the DUT generates a second response in response to providing the test signal to the predefined circuit path, wherein the second response is indicative of a conductive or not conductive status of the predefined circuit path.

4. The test system of claim 1, wherein the DUT is placed in a test mode to test the intermediary device.

5. The test system of claim 4, wherein the DUT is placed in the test mode in accordance with a JTAG IEEE 1149-1 standard, wherein a boundary scan chain of the DUT is configurable to include the predefined circuit path.

6. The test system of claim 5, wherein the testing of the intermediary device includes testing a predefined component of the intermediary device, wherein the DUT is configurable to couple the predefined component to the boundary scan chain, wherein the DUT is operable to provide the test signal to the predefined component to verify operational status.

7. The test system of claim 6, wherein another DUT is coupled to the intermediary device, wherein the another DUT is tested in response to verifying the predefined component is substantially free from defects.

8. The test system of claim 1, wherein the test signal is a high-speed digital signal having a frequency less than approximately 20 GHz.

9. The test system of claim 1, wherein the DUT is at least one of a microprocessor, an application specific integrated circuit (ASIC), a digital signal processor, a radio frequency chip, a memory, a microcontroller and a system-on-a-chip or a combination thereof.

10. A method for testing an intermediary device coupled to a device under test (DUT), the method comprising:
providing a test signal to the DUT via a first circuit path on the intermediary device;
receiving a first response from the DUT to verify that the DUT is substantially free from defects;
configuring the DUT to include a second circuit path on the intermediary device, wherein the second circuit path is coupled in series with the first circuit path;
providing the test signal to the DUT, wherein the DUT provides the test signal to the second circuit path; and
receiving a second response from the DUT to verify that the second circuit path is substantially free from defects.

11. The method of claim 10 further comprising:
placing the DUT in a test mode prior to providing the test signal via the first circuit path.

12. The method of claim 11, wherein the DUT is placed in the test mode in accordance with a JTAG IEEE 1149-1 standard, wherein the configuring of the DUT includes configuring a boundary scan chain of the DUT to include the second circuit path.

13. The method of claim 10, wherein receiving the first response also verifies continuity of the first circuit path.

14. The method of claim 10, wherein the DUT is at least one of a microprocessor, an application specific integrated circuit (ASIC), a digital signal processor, a radio frequency chip, a memory, a microcontroller and a system-on-a-chip or a combination thereof.

15. The method of claim 10 further comprising:
configuring the DUT to include a predefined component of the intermediary device, wherein the predefined component is coupled in series with the first circuit path;
providing the test signal to the DUT via the predefined component; and receiving a third response from the DUT to verify that the predefined component is substantially free from defects.

16. The method of claim 15, wherein the predefined component is selectable to be at least one of an integrated circuit (IC), a resistor, a capacitor, an inductor and a relay.

17. The method of claim 15, wherein another DUT is coupled to the intermediary device, wherein the another DUT is tested in response to verifying the predefined component is substantially free from defects.

18. A method for testing a relay included on an intermediary device, the intermediary device being coupled to a device under test (DUT), the method comprising:
placing the DUT in a test mode;
closing the relay to enable a loop back path;
configuring a boundary scan chain for the DUT, wherein the boundary scan chain originates with a TDI input and terminates with a TDO output, wherein the relay is coupled to the boundary scan chain via a primary output and a primary input;
providing a predefined logic signal to the TDI input; and
verifying whether the predefined logic signal is received at the TDO output.

19. The method of claim 18, wherein the DUT is at least one of a microprocessor, an application specific integrated circuit (ASIC), a digital signal processor, a radio frequency chip, a memory, a microcontroller and a system-on-a-chip or a combination thereof.

20. The method of claim 18, wherein the test mode is in accordance with a JTAG IEEE 1149-1 standard.
